(19) United States
(12) Patent Application Publication
(10) Pub. No.: US 2011/0194207 A1
(43) Pub. Date: Aug. 11, 2011

(54) METHOD OF PRODUCING MAGNETIC STORAGE MEDIUM, MAGNETIC STORAGE MEDIUM AND INFORMATION STORAGE DEVICE

(75) Inventors: Kenji Sato, Kawasaki (JP); Tsutomu Tanaka, Kawasaki (JP); Takuya Uzumaki, Kawasaki (JP); Tsutomu Nishihashi, Susono (JP); Tadashi Morita, Tsukuba (JP); Kazuhiro Watanabe, Susono (JP)

(73) Assignee: ULVAC, INC., Chigasaki-shi, Kanagawa (JP)

(21) Appl. No.: 13/123,287

(22) PCT Filed: Nov. 18, 2009
(86) PCT No.: PCT/JP2009/069561

§ 371 Date: Apr. 8, 2011

(30) Foreign Application Priority Data
Nov. 19, 2008 (JP) 2008-295485

(51) Int. Cl. G11B 21/02; C23C 14/14; C23C 14/04; G11B 5/66

(52) U.S. Cl. 360/75; 427/531; 427/526; 428/829; G9B/21.003

(57) ABSTRACT

It is an object to provide a simple method capable of producing a magnetic storage medium, a magnetic storage medium and an information storage device which may be produced by a simple production method with a high recording density, and a magnetic disk is produced by a production method having: a film-forming process of forming, on a substrate 61, a magnetic film made of a Co—Cr—Pt alloy and having a thickness of less than 10 nm; and an ion injection process of forming, by reducing saturation magnetization by locally injecting ions into a point other than plural points that become magnetic dots on each of which information is magnetically recorded, a between-dot separator having saturation magnetization smaller than saturation magnetization of the magnetic dots, between the magnetic dots.

### TECHNICAL FIELD

The present case relates to a method of producing a magnetic storage medium, the magnetic storage medium, and an information storage device including the magnetic storage medium.

### BACKGROUND ART

Hard Disk Drives (HDD) have been in the mainstream of information storage device, as a mass-storage device capable of high-speed access and high-speed transfer of data. As to this HDD, the areal recording density has increased at a high annual rate so far, and a further improvement of the recording density is still desired even at present.

In order to improve the recording density of the HDD, it is necessary to reduce the track width or shorten the recording bit length, but when the track width is reduced, the so-called interference easily occurs between adjacent tracks. This interference is, namely, a generic name for a phenomenon in which a track next to a target track is overwritten with magnetic recording information at the time of recording, or a phenomenon in which crosstalk occurs due to a leakage magnetic field from a track next to a target track at the time of reproduction. Either of these phenomena becomes a factor that results in a drop in S/N ratio of regenerative signal, causing deterioration in an error rate.

On the other hand, when the recording bit length is shortened, there occurs a thermal fluctuation phenomenon in which performance of keeping the recording bit for a long time decreases.

As a way of avoiding these interference and thermal fluctuation phenomenon and thereby realizing a short bit length or a high track density, a magnetic storage medium of a discrete track type and a magnetic storage medium of a bit-patterned type are proposed (for example, see PTL 1). In particular, in the magnetic storage medium of the bit-patterned type, the position of a recording bit is predetermined, a dot made of a magnetic material is formed in the predetermined position of the recording bit, and a part between the dots is made of a non-magnetic material. When the dots made of the magnetic material are thus separated from each other, the magnetic interaction between the dots is small, and the above-described interference and thermal fluctuation phenomenon are evaded.

Here, as a method of producing the magnetic storage medium of the bit-patterned type, a conventional production method proposed in PTL 1 and the like will be described.

FIG. 1 is a diagram that illustrates the conventional production method of producing the magnetic storage medium of the bit-patterned type.

In the conventional production method, first, a magnetic film 2 is formed on a substrate 1 in a film-forming process (A).

Next, in a nano-imprint process (B), a resist 3 made of a UV curable resin is applied onto the magnetic film 2, and a mold 4 having nano-sized holes 4a is mounted on the resist 3. As a result of this, the resist 3 enters the nano-sized holes 4a, thereby forming dots 3a of the resist 3. And then, the resist 3 is irradiated with ultraviolet light over the mold 4 so that the resist 3 is cured and the dots 3a are printed on the magnetic film 2. Further, after the resist 3 is cured, the mold 4 is removed.

Subsequently, etching is performed in an etching process (C), so that the magnetic film is removed, while leaving magnetic dots 2a protected by the dots 3a of the resist 3. After the etching, the dots 3a of the resist 3 are removed by a chemical process, so that only the magnetic dots 2a remain on the substrate 1.

And then, in a filling process (D), a part between the magnetic dots 2a is filled with a non-magnetic material. Subsequently, the surface is flattened in a flattening process (E), so that a magnetic storage medium 6 of the bit-patterned type is completed (F).

According to such a conventional production method, in order to stabilize the floating property of a magnetic head above the magnetic storage medium 6, the flattening with high accuracy is necessary in the flattening process (E). Therefore, there arise such a problem that a very complicated manufacturing process needs to be performed and such a problem that the manufacture cost increases.

Here, it is known that when ions are injected into a magnetic film, the magnetic property of the magnetic film changes (for example, see PTL 2). And, there is proposed a processing method (ion doping system) of forming a separation state of dots by injecting ions into a magnetic film and thereby changing a magnetic state locally (for example, see PTL 3 and PTL 4).

According to this ion doping system, the magnetic property is changed by injecting the ions and thus, complicated manufacturing processes such as the etching, the filling and the flattening are unnecessary, making it possible to suppress an increase in production cost to a large extent.

### CITATION LIST

### Patent Literature

PTL 1: Japanese Patent No. 1888363
PTL 2: Japanese Laid-open Patent Publication No. 07-141641
PTL 3: Japanese Laid-open Patent Publication No. 2002-288813
PTL 4: Japanese Laid-open Patent Publication No. 2006-309841

### SUMMARY OF INVENTION

### Technical Problem

However, mere application of the ion doping system reduces only magnetic anisotropy, and hardly changes saturation magnetization and thus does not solve the interference due to magnetic interaction and thermal fluctuation described above and therefore, practical use is not attained.

Incidentally, up to this point, by taking the magnetic storage of the bit-patterned type as an example, there has been described such a problem that practical use of the above-described simple production method has not achieved. However, such a problem is not limited to the magnetic storage medium of the bit-patterned type, and applies to, for example, the magnetic storage medium of the discrete track type. In other words, such a problem commonly applies to a magnetic storage medium having a magnetic section in which information is magnetically recorded, and a low magnetic section having saturation magnetization smaller than the saturation magnetization of the magnetic section.

In view of the foregoing circumstances, it is an object of the present application to provide a simple production method capable of producing a magnetic storage medium, the magnetic storage medium and an information storage device capable of being produced by such a simple production method.

### Technical Solution

A basic mode of the method of producing a magnetic storage medium includes:
magnetic-film-forming including forming a magnetic film having a thickness of less than 10 nm with a Co—Cr—Pt-based alloy on a substrate; and
ion-injection including locally injecting an ion into an area other than a predetermined protected area, on the magnetic film.

A basic mode of the magnetic storage medium includes:
a substrate;
a magnetic section that has a magnetic film formed in a thickness of less than 10 nm with a Co—Cr—Pt-based alloy on the substrate, and on which information is magnetically recorded; and
a low magnetic section that has an injected film in which an ion is injected into a magnetic film continuing to the magnetic film of the magnetic section, and has saturation magnetization smaller than saturation magnetization of the magnetic section.

A basic mode of the information storage device includes:
a magnetic storage medium that includes:
a substrate;
a magnetic section which has a magnetic film formed in a thickness of less than 10 nm with a Co—Cr—Pt-based alloy on the substrate and, and on which information is magnetically recorded; and
a low magnetic section which has an injected film in which ions are injected into a magnetic film continuing to the magnetic film of the magnetic section, and has saturation magnetization smaller than saturation magnetization of the magnetic section;
a magnetic head that approaches or contacts the magnetic storage medium, to perform at least one of magnetically recording information and magnetically reproducing information for the magnetic section; and
a head-position control mechanism that moves the magnetic head relatively to a surface of the magnetic storage medium, to position the magnetic head over the magnetic section on or from which the information is to be written or reproduced by the magnetic head.

Here, the “Co—Cr—Pt-based alloy” refers to a Co—Cr—Pt alloy, or an alloy or the like in which another element such as Ta, Ni, B, Cu and SiO₂ is added to the Co—Cr—Pt alloy within a composition range in which the magnetic property or the like of the Co—Cr—Pt alloy is not impaired.

According to the method of producing the magnetic storage medium in the basic mode, for example, it is possible to form, by the ion injection, a low magnetic section occupying a part between magnetic dots of the magnetic storage medium of the bit-patterned type, or a low magnetic section occupying both sides of a track of the magnetic storage medium of the discrete track type. Therefore, complicated manufacturing processes such as etching, filling, flattening and the like become unnecessary and thus, the method of producing the magnetic storage medium of this basic mode is a simple production method. Further, according to the magnetic storage medium and the information storage device of the basic modes, production by the simple production method is possible. Here, conventionally, a magnetic film made of a Co—Cr—Pt-based alloy has been in such a situation that it is difficult to sufficiently reduce the saturation magnetization by ion injection using an inert gas of Ar or the like. However, for this magnetic film made of the Co—Cr—Pt-based alloy, the developer of this case has found that the saturation magnetization may be effectively reduced by formation with a film thickness of less than 10 nm. According to each of the above-described basic modes, the magnetic film made of the Co—Cr—Pt-based alloy is formed to have the film thickness of less than 10 nm by which an effective reduction of the saturation magnetization is possible. In other words, according to these basic modes, by the above-described simple production method that locally reduces the saturation magnetization of the magnetic film, the magnetic storage medium and the information storage device of the bit-patterned type and the discrete track type may be practically produced.

### ADVANTAGEOUS EFFECTS

As described above, according to the present case, it is possible to obtain the simple production method capable of producing the magnetic storage medium, and the magnetic storage medium and the information storage device which may be produced by such a simple production method.

### BRIEF DESCRIPTION OF DRAWINGS

FIG. 1 is a diagram that illustrates a conventional production method of producing a magnetic storage medium of the bit-patterned type.

FIG. 2 is a diagram that illustrates an internal structure of a Hard Disk Device (HDD) that is an exemplary embodiment of the information storage device.

FIG. 3 is a perspective view that schematically illustrates a structure of the magnetic disk illustrated in FIG. 2.

FIG. 4 is a diagram that illustrates a method of producing the magnetic disk illustrated in FIG. 2 and FIG. 3.

FIG. 5 is a diagram that illustrates an example.

FIG. 6 is a graph that indicates an effect of the ion injection in each of the example and the comparative example.

FIG. 7 is a graph that indicates the dependence of the saturation magnetization on the amount of injected ions, for each of the magnetic film formed to have the film thickness of 5 nm and the magnetic film formed to have the film thickness of 10 nm.

### DESCRIPTION OF EMBODIMENTS

Exemplary embodiments of the method of producing the magnetic storage medium, the magnetic storage medium and the information storage device for which the basic modes have been described above will be described below with reference to the drawings.

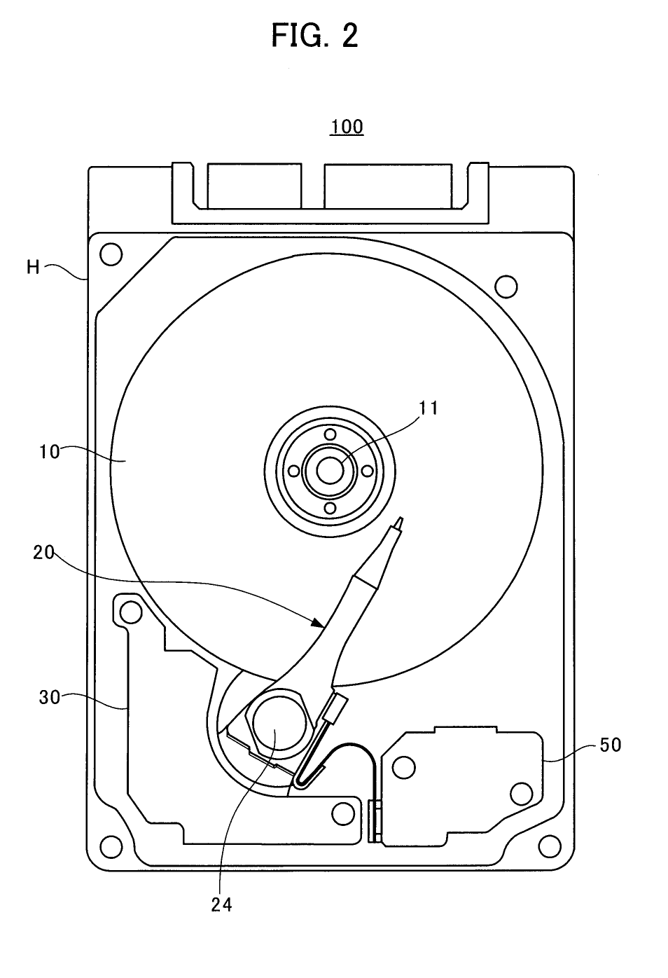

FIG. 2 is a diagram that illustrates an internal structure of a Hard Disk Device (HDD) that is an exemplary embodiment of the information storage device.

A Hard Disk Device (HDD) 100 illustrated in this diagram is incorporated into a host device such as a personal computer, and used as an information storage means in the host device.

In this hard disk device 100, two or more circular-plate-like magnetic disks 10 are stacked in a depth direction of the diagram, and housed in a housing H. This magnetic disk 10 is equivalent to an exemplary embodiment of the magnetic storage medium for which the basic mode has been described above.

Here, with respect to the basic modes of the magnetic storage medium and the information storage device, such an applied mode that “the magnetic section is each of magnetic dots which are regularly arranged in plural arrays on the substrate, and in each of which information is magnetically recorded, and
the low magnetic section is a between-dot separator provided between the magnetic dots and obstructing mutual magnetic coupling of the magnetic dots” is preferable.

This applied mode is equivalent to a magnetic storage medium of the bit-patterned type in which magnetic dots where bit information is recorded are provided beforehand at the respective locations on a substrate.

The magnetic disk 10 of FIG. 2 is a magnetic storage medium of the bit-patterned type, and is equivalent to an exemplary embodiment of this applied mode. Further, this magnetic disk 10 is also a so-called perpendicular magnetic storage medium in which on each magnetic dot, information is recorded in the form of magnetic pattern by magnetization in a direction perpendicular to the front and back faces. Furthermore, it is also applicable to a so-called in-plane magnetic storage medium in which information is recorded in the form of magnetic pattern by magnetization in a longitudinal direction with respect to the front and back faces.

This magnetic disk 10 rotates about a disk spindle 11 in the housing H.

Further, in the housing H of the hard disk device 100, a swing arm 20 that moves along the front and back faces of the magnetic disk 10, an actuator 30 used for driving the swing arm 20 and a control circuit 50 are also housed.

The swing arm 20 holds, at the tip, a magnetic head 21 that performs writing and reading of information to and from the front and back faces of the magnetic disk 10. Further, the swing arm 20 is pivotably supported in the housing H by a bearing 24. And, this swing arm 20 is pivoted within a predetermined angle range about the bearing 24, so that the magnetic head 21 is caused to move along the front and back faces of the magnetic disk 10. This magnetic head is equivalent to an example of the magnetic head in the above-described basic mode of the information storage device.

The reading and writing of information by the magnetic head 21 and the movement of the arm 30 are controlled by the control circuit 50, and the exchange of information with the host device also is performed through this control circuit 50.

The combination of the swing arm 20, the bearing 24, the actuator 30 and the control circuit 50 is equivalent to an example of the head-position control system in the above-described basic mode of the information storage device.

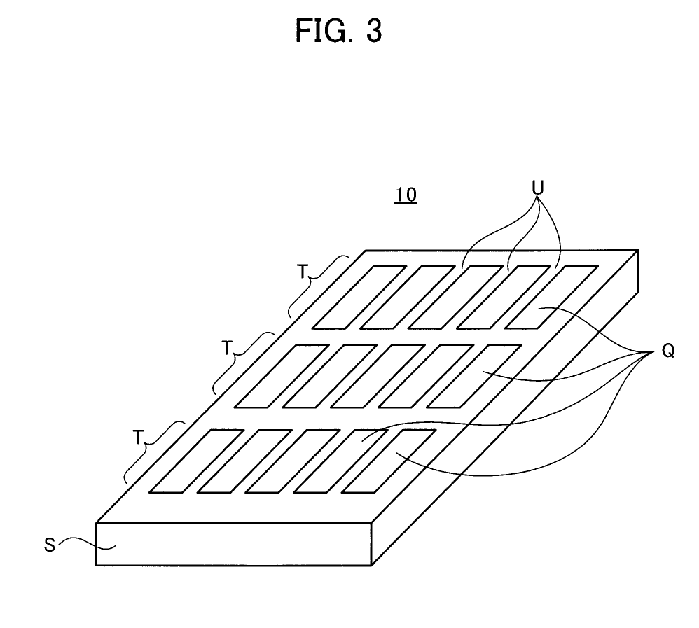

FIG. 3 is a perspective view that schematically illustrates the structure of the magnetic disk illustrated in FIG. 2.

In this FIG. 3, a part cut from the circular-plate-like magnetic disk is illustrated.

The magnetic disk 10 illustrated in FIG. 3 has such a structure that plural magnetic dots Q are arranged in regular arrays on a substrate S. Information corresponding to 1 bit is magnetically recorded in each of the magnetic dots Q. The magnetic dots Q are arranged to be shaped like a circular orbit around the center of the magnetic disk 10, and a column of the magnetic dots forms a track T. The substrate S is equivalent to an example of the substrate in the above-described basic modes. Further, the magnetic dot Q is equivalent to an example of the magnetic section in the above-described basic modes, and is also equivalent to an example of the magnetic dot in the applied mode corresponding to the magnetic storage medium of the bit-patterned type.

Furthermore, a part between the magnetic dots Q is a between-dot separator U in which the magnetic anisotropy and the saturation magnetization are lower than the magnetic anisotropy and the saturation magnetization of the magnetic dots Q, and which magnetically separates the magnetic dots Q. The magnetic interaction between the magnetic dots Q is small due to this between-dot separator U. This between-dot separator U is equivalent to an example of the low magnetic section in the above-described basic modes, and is also equivalent to an example of the between-dot separator in the applied mode corresponding to the magnetic storage medium of the bit-patterned type.

When the magnetic interaction between the magnetic dots Q is thus small, even at the time of recording and reproducing information to and from the magnetic dot Q, the magnetic interaction between the tracks T is small and thus, the so-called interference between the tracks is small. Further, in each of the magnetic dots Q, the border of a recorded information bit does not fluctuate by heat, and the so-called thermal fluctuation phenomenon is evaded. Thus, according to the magnetic disk 10 of the bit-patterned type as illustrated in this FIG. 3, reduction of the track width and shortening of the recording bit length are possible, and the magnetic storage medium with a high recording density may be obtained.

A method of producing this magnetic disk 10 will be described below.

The method of producing this magnetic disk 10 is equivalent to an exemplary embodiment of the method of producing the magnetic storage medium for which the basic mode has been described above.

Here, with respect to the basic mode of this method of producing the magnetic storage medium, such an applied mode that “the ion-injection includes using ions of at least one kind of oxygen ion, nitrogen ion and fluorine ion” is conceivable.

This applied mode is equivalent to a method of producing a magnetic storage medium of the bit-patterned type. The method of producing the magnetic disk 10 to be described below is also equivalent to an exemplary embodiment of this applied mode.

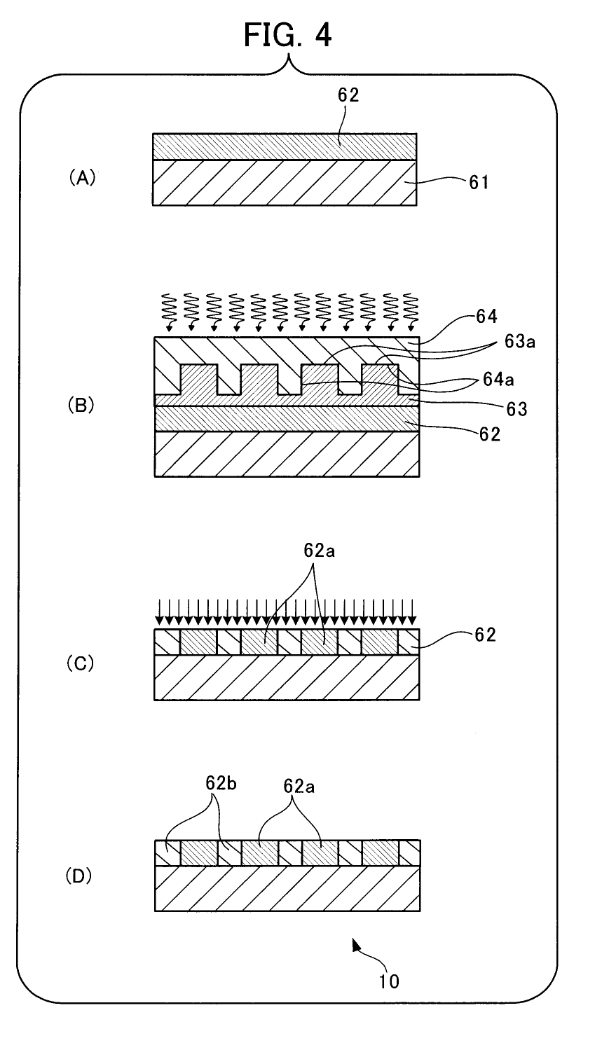

FIG. 4 is a diagram that illustrates the method of producing the magnetic disk illustrated in FIG. 2 and FIG. 3.

In the production method illustrated in this FIG. 4, at first, a magnetic film 62 is formed on a glass substrate 61 in a film-forming process (A). This film-forming process (A) is equivalent to an example of the magnetic-film forming step in the above-described basic mode of the method of producing the magnetic storage medium, and this magnetic film 62 is a magnetic film made of a Co—Cr—Pt-based alloy and having a thickness of less than 10 nm.

Next, in a nano-imprint process (B), a resist 63 made of a UV curable resin is applied onto the magnetic film 62, a mold 64 having nano-sized holes 64a is mounted on the resist 63. This results in the resist 63 entering the nano-sized holes 64a, and thereby dots 63a of the resist 63 are formed. And, the resist 63 is irradiated with ultraviolet light over the mold 64, so that the resist 63 is cured and the dots 63a are printed on the magnetic film 62. Further, after the resist 63 is cured, the mold 64 is removed.

After the nano-imprint process (B), the flow advances to an ion injection process (C). In this ion injection process (C), ions of any one kind of oxygen ions, nitrogen ions and fluorine ions are emitted from above the magnetic film 62 on which the dots 63a are printed. As a result, the ions are injected into the magnetic film 62 while magnetic dots 62a protected by the dots 63a of the resist 63 are left so that the saturation magnetization is reduced. Here, in the present embodiment, the magnetic film 62 is made of the Co—Cr—Pt-based alloy having the thickness of less than 10 nm and thus, the saturation magnetization of the magnetic film 62 may be reduced by the ion injection effectively. This ion injection process (C) is equivalent to an example of the ion injection step in the above-described basic mode. Further, this ion injection process (C) is equivalent to an example of the ion injection step in the applied mode corresponding to the method of producing the magnetic storage medium of the bit-patterned type.

Here, for the above-described basic mode, such an applied mode that “the ion-injection includes using ions of at least one kind of oxygen ion, nitrogen ion and fluorine ion” is preferable.

The reason is because the oxygen ions, the nitrogen ions and the fluorine ions may degrade the magnetic property of the magnetic film more effectively than when other ions are injected into the magnetic film made of a Co—Cr—Pt-based alloy. As this factor, conventionally, inert-gas Ar ions having a large atomic radius have been used. In the present invention, ions of an element having a comparatively small atomic radius such as the oxygen ions, the nitrogen ions and the fluorine ions are applied, so that the ions may effectively break into the crystal lattice of the Co—Cr—Pt-based alloy. And, it is understood that the Curie temperature is decreased by causing distortion in the lattice, and as a result, the saturation magnetization at room temperature may be reduced.

The ion injection process (C) in FIG. 4 is also equivalent to an example of the ion injection step in this applied mode.

Further, for the above-described basic mode, such an applied mode that “there is further provided mask-formation including forming a mask that obstructs injection of the ion into the protected area, wherein

the ion-injection includes locally injecting, by applying the ion from above the magnetic film on which the mask is formed, the ions into an area other than the protected area protected by the mask” is preferable.

According to this applied mode, an area where the ion injection is unnecessary is reliably protected by the mask and thus, formation accuracy of the magnetic dot is high. The nano-imprint process (B) in FIG. 4 is equivalent to an example of the mask formation step in this applied mode, and the ion injection process (C) is equivalent to an example of the ion injection step in this applied mode.

Furthermore, for this applied mode having the mask formation step, an applied mode in which “the mask-formation includes forming the mask with a resist” and an applied mode in which “the mask-formation includes forming the mask with a resist, by a nano-imprint process” are further preferable.

Based on the mask formation by the resist, technically stable and accurate mask formation may be expected, and the mask formation by the nano imprint process may easily create a mask pattern in a nano level and thus is desirable. The nano-imprint process (B) illustrated in this FIG. 4 is equivalent to an example of the mask formation step in these further preferable applied modes.

Incidentally, in the above-described nano-imprint, the resist is not completely removed even in the area into which the ions should be injected. However, the ions penetrate the resist at a location where the resist is thin and are injected into the magnetic film 62, whereas at a location where the resist is thick (namely, a location where the dots 63a are formed), the ions are stopped at the resist and do not reach the magnetic film. For this reason, it is possible to form a desired dot pattern.

Further, in the ion injection process (C) illustrated in FIG. 4, an ionic acceleration voltage is set so that the ions are injected into a central part of the magnetic film 62. This acceleration voltage varies depending on the type of ions, and varies depending on the depth to the central part of the magnetic film and the material.

In the magnetic film 62 at the area into which the ions are injected in this ion injection process (C), the ions are accumulated inside, and the crystal structure is warped, and a coercive force and the saturation magnetization fall. After the ion injection, the dots 63a of the resist are removed by a chemical process.

Through such an ion injection process (C), a between-dot separator 62b is formed between the magnetic dots 62a to separate the magnetic mutual interaction between the magnetic dots 62a, so that the magnetic storage medium 10 of the bit-patterned type is completed (D). In the between-dot separators 62b, the saturation magnetization is sufficiently lower than the saturation magnetization of the magnetic dots 62a and thus, information is recorded only in the magnetic dots 62a, while information is not recorded in the between-dot separators 62b.

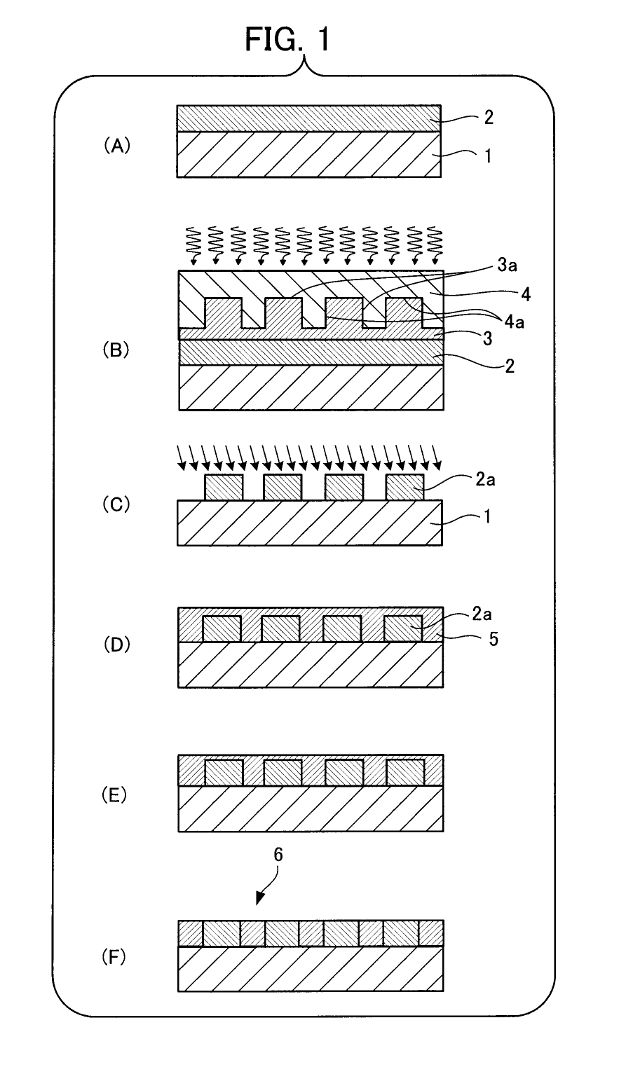

In the magnetic storage medium 10 produced in the production method illustrated in this FIG. 4, smoothness between the magnetic dots 62a and the between-dot separators 62b forming the surface is the smoothness in the magnetic film 62 formed in the film-forming process (A) which is maintained as it is. For this reason, the flattening process of the conventional technique as illustrated in FIG. 1 is unnecessary, and the production method illustrated in this FIG. 4 is a simple method.

Furthermore, in the production method illustrated in this FIG. 4, the magnetic dots 62a are protected by the dots 63a of the resist printed on the magnetic film 62. Therefore, the entire surface of the magnetic storage medium 10 may be irradiated with the ions at a time, and the ion injection into the necessary area may be sufficiently obtained by the ion irradiation for several seconds and thus, the mass productivity is not impaired.

In an example to be described below, the production method illustrated in this FIG. 4 is applied to specific materials and the like, and the technical effect was verified.

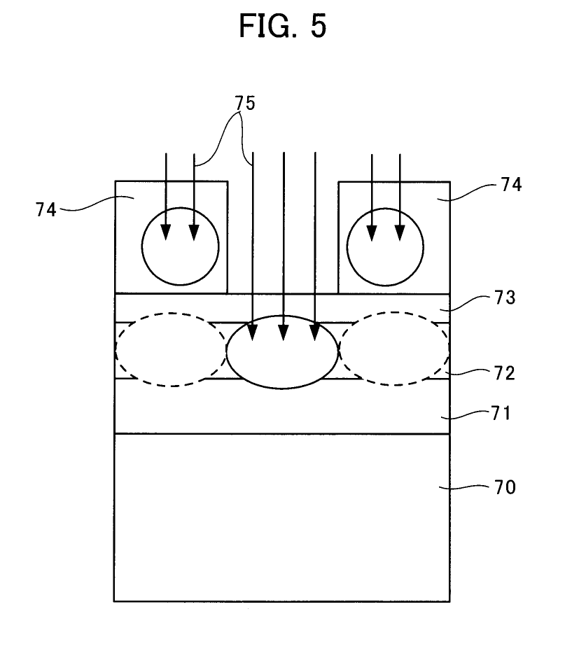

FIG. 5 is a diagram that illustrates the example.

A glass substrate 70 washed well was set in a magnetron sputtering device, and evacuation is performed up to 5×10⁻⁵ Pa or less. Subsequently, at an Ar gas pressure of 0.67 Pa, without heating the glass substrate 70, a 5-nm-thick film of (001) crystal-oriented hcp-Ru was formed as a base layer 71 for making a magnetic layer have crystal orientation. As to the process for forming this base layer 71, the illustration is omitted in the production method depicted in FIG. 4.

Subsequently, successively without returning to the air pressure, a magnetic film 72 formed of a Co—Cr—Pd alloy was formed at the Ar gas pressure of 0.67 Pa.

Incidentally, here, the magnetic film 72 having a film thickness in a range of 5 nm or more and less than 10 nm was formed.

After the magnetic film 72 was formed, a 4-nm-thick film of diamond-like carbon was formed as a protective layer 73. The illustration of the process of forming this protective layer 73 also is omitted in the production method illustrated in FIG. 4.

A resist was applied onto the protective layer 73, and by using the nano-imprint process, a columnar resist pattern 74 having a diameter of 18 nm to 60 nm was formed.

From above the resist pattern 74, nitrogen ions 75 accelerated at 6 keV were emitted and injected into the magnetic film 72. As mentioned earlier, the ionic acceleration voltage was set so as to inject the ions into the central part of the magnetic film 72.

Incidentally, considering a realistic film thickness of the magnetic film and damage to the magnetic film at the time of the ion injection, it is desirable that the ionic acceleration voltage be 1 keV or more and 10 keV or less.

After the ion injection, the resist pattern 74 was removed by SCl cleaning, and thereby the example was obtained.

With respect to the above-described example, a comparative example was created by forming a magnetic film 72 having a thickness in a range of 10 nm or more and 20 nm or less, and performing the ion injection similar to the above-described example.

The effect of the ion injection in each of the example and the comparative example thus obtained was verified.

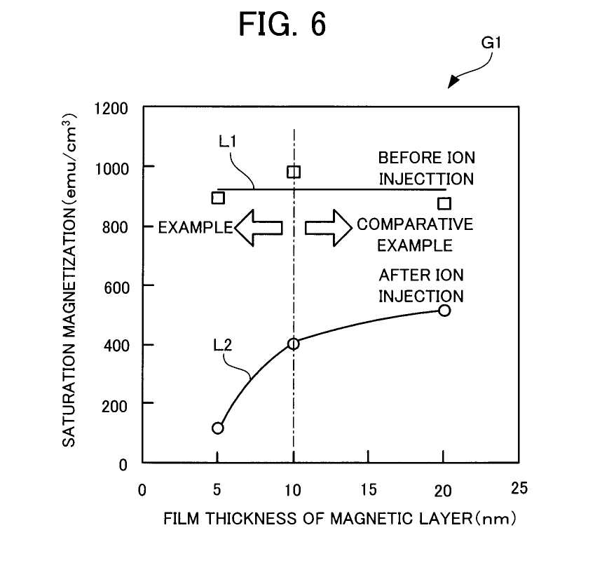

FIG. 6 is a graph that indicates the effect of the ion injection in each of the example and the comparative example.

In the graph G1 illustrated in this FIG. 6, the film thickness of the magnetic film 72 is on the horizontal axis, and the saturation magnetization of the magnetic film 72 is on the vertical axis. And, for both of the example and the comparative example, a correspondence of the film thickness change and the saturation magnetization is illustrated. Further, for both of the example and the comparative example, the correspondence before the ion injection is indicated by a first line L1 linking square marks, and the correspondence after the ion injection is indicated by a second line L2 linking circular marks. Of each of these lines L1 and L2, a part within a range in which the film thickness is 5 nm or more and less than 10 nm corresponds to the example, whereas a part within a range in which the film thickness is 10 nm or more and 20 nm or less corresponds to the comparative example.

The second line L2 in the graph G1 of FIG. 6 falls leftward. Further, the second line L2 bends at the film thickness of 10 nm, and the falling inclination becomes acute. From the shape of this second line L2, first, it is found that the thinner the film thickness of the magnetic film is, the greater the effect of reducing the saturation magnetization by the ion injection becomes. Further, from the bending of this second line L2, it is found that beyond the film thickness of 10 nm, as the film thickness becomes thinner than 10 nm, the effect of reducing the saturation magnetization becomes greater sharply.

Next, into the magnetic film 72 (equivalent to the example) formed to have a film thickness of 5 nm, nitrogen ions are injected, while gradually increasing the mount of injection and thereby, dependence of the saturation magnetization on the amount of injected ions was determined. Also, into the magnetic film 72 (equivalent to the comparative example) formed to have a film thickness of 10 nm, nitrogen ions are injected, while gradually increasing the mount of injection and thereby, dependence of the saturation magnetization on the amount of injected ions was determined.

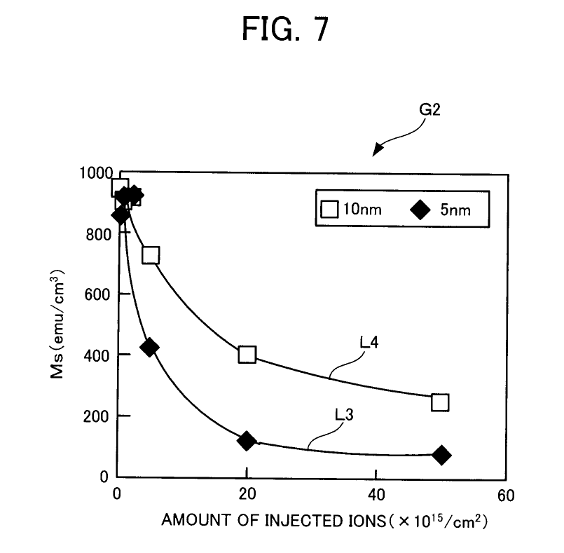

FIG. 7 is a graph that indicates the dependence of the saturation magnetization on the amount of injected ions, for each of the magnetic film formed to have the film thickness of 5 nm and the magnetic film formed to have the film thickness of 10 nm.

In a graph G2 illustrated in this FIG. 7, the ion injection is on the horizontal axis, while the saturation magnetization of the magnetic film 72 is on the vertical axis. The dependence of the saturation magnetization on the amount of injected ions in the magnetic film (equivalent to the example) formed to have the film thickness of 5 nm is indicated by a third line L3 linking diamond marks. Further, the dependence of the saturation magnetization on the amount of injected ions in the magnetic film (equivalent to the comparative example) formed to have the film thickness of 10 nm indicated by a fourth line L4 linking square marks.

Here, as described above with reference to the second line L2 in the graph G1 of FIG. 6, beyond the film thickness of 10 nm, as the film thickness becomes thinner than 10 nm, the effect of reducing the saturation magnetization becomes greater sharply. The film thickness of 10 nm corresponding to the fourth line L4 of FIG. 7 is the film thickness at the boundary from which this effect of reducing the saturation magnetization becomes greater sharply.

In this fourth line L4, the reduction effect weakens around where the saturation magnetization becomes less than 400 emu/cm³. Here, it is desirable that as the between-dot separator 62b (see FIG. 4), the saturation magnetization decrease to 20% or less of the saturation magnetization before the ion injection. However, from the shape of this fourth line L4, it is found that it is difficult to obtain the saturation magnetization lower than 200 emu/cm³ corresponding to 20% of the saturation magnetization before the ion injection, in the magnetic film 72 having the film thickness of 10 nm.

On the other hand, in the magnetic film 72 having the film thickness of 5 nm, it is found from the shape of the third line L3 in the graph G2 of FIG. 7 that the saturation magnetization lower than 200 emu/cm³ corresponding to 20% of the saturation magnetization before the ion injection may be sufficiently obtained by the amount of injected ions of 1×10¹⁶ atoms/cm³ or more.

From the lines L3 and L4 in the graph G2 of this FIG. 7, and the line L2 in the graph G1 of FIG. 6 described above, it may be said that it is appropriate to make, as described in the above basic mode, the film-thickness range of the magnetic film formed in the magnetic-film forming step and made of the Co—Cr—Pt-based alloy be “less than 10 nm.”

As described above, it was found that by making the film thickness of the magnetic film made of the Co—Cr—Pt-based alloy be “less than 10 nm”, the great effect of reducing of the saturation magnetization by the ion injection was obtained. From this, it is apparent that in the method of producing the magnetic storage medium employing the ion doping system, by forming the magnetic film made of the Co—Cr—Pt-based alloy in the above-described film-thickness range, the saturation magnetization may be sufficiently reduced locally. Further, according to such a method of producing the magnetic storage medium, it is possible to practically produce a bit-patterned type of magnetic storage medium with a high recording density.

Incidentally, in the above description, the magnetic storage medium of the bit-patterned type has been taken as an example of the magnetic storage medium, but the magnetic storage medium is not limited to the bit-patterned type and may be of, for example, the discrete track type.

Further, in the above description, the Co—Cr—Pt alloy has been taken as an example of the Co—Cr—Pt-based alloy that forms the magnetic film, but the Co—Cr—Pt-based alloy is not limited to this. This Co—Cr—Pt-based alloy may be an alloy or the like in which another element such as Ta, Ni, B, Cu, SiO₂ is added to the Co—Cr—Pt alloy, within a composition range in which the magnetic property of the Co—Cr—Pt alloy is not impaired.

Furthermore, in the above description, use of the resist pattern as a preferable mask for forming the magnetic dots has been discussed as an example. In contrast, in the ion injection in the above-described basic modes, a process in which a stencil mask is disposed so as not to touch the surface of the medium and the ions are injected may be employed. According to this process, the resist application and the resist removal may be omitted.

Still Furthermore, in the above description, use of the nano-imprint process has been stated as the best example of the patterning of the resist, but electron beam exposure may be used in the patterning.

Moreover, in the above description, ions of any one kind of the oxygen ions, the nitrogen ions and the fluorine ions have been taken as an example of the injected ions, but the injected ions are not limited to this, and may be mixed ions of these ions.

1. A method of producing a magnetic storage medium, the method characterized by comprising:
magnetic-film-forming including forming a magnetic film having a thickness of less than 10 nm with a Co—Cr—Pt-based alloy on a substrate; and
ion-injection including locally injecting an ion into an area other than a predetermined protected area, on the magnetic film.

2. The method of producing the magnetic storage medium according to claim 1, characterized in that the ion-injection includes locally injecting, by using a plurality of points arranged regularly in a direction in which the magnetic film spreads as the protected area, the ion between the plurality of points.

3. The method of producing the magnetic storage medium according to claim 1, characterized in that the ion-injection includes using ions of at least one kind of oxygen ion, nitrogen ion and fluorine ion.

4. The method of producing the magnetic storage medium according to claim 1, characterized by further comprising mask-formation including forming a mask that obstructs injection of the ion into the protected area, wherein
the ion-injection includes locally injecting, by applying the ion from above the magnetic film on which the mask is formed, the ions into an area other than the protected area protected by the mask.

5. The method of producing the magnetic storage medium according to claim 4, characterized in that the mask-formation includes forming the mask with a resist.

6. The method of producing the magnetic storage medium according to claim 4, characterized in that the mask-formation includes forming the mask with a resist, by a nano-imprint process.

7. A magnetic storage medium comprising:
a substrate;
a magnetic section that has a magnetic film formed in a thickness of less than 10 nm with a Co—Cr—Pt-based alloy on the substrate, and on which information is magnetically recorded; and
a low magnetic section that has an injected film in which an ion is injected into a magnetic film continuing to the magnetic film of the magnetic section, and has saturation magnetization smaller than saturation magnetization of the magnetic section.

8. The magnetic storage medium according to claim 7, characterized in that the magnetic section is each of magnetic dots which are regularly arranged in a plurality of arrays on the substrate, and in each of which information is magnetically recorded, and
the low magnetic section is a between-dot separator provided between the magnetic dots and obstructing mutual magnetic coupling of the magnetic dots.

9. An information storage device characterized by comprising:
a magnetic storage medium that includes:
a substrate;
a magnetic section which has a magnetic film formed in a thickness of less than 10 nm with a Co—Cr—Pt-based alloy on the substrate and, and on which information is magnetically recorded; and
a low magnetic section which has an injected film in which ions are injected into a magnetic film continuing to the magnetic film of the magnetic section, and has saturation magnetization smaller than saturation magnetization of the magnetic section;
a magnetic head that approaches or contacts the magnetic storage medium, to perform at least one of magnetically recording information and magnetically reproducing information for the magnetic section; and
a head-position control mechanism that moves the magnetic head relatively to a surface of the magnetic storage medium, to position the magnetic head over the magnetic section on or from which the information is to be written or reproduced by the magnetic head.

10. The information storage device according to claim 9, characterized in that the magnetic section is each of magnetic dots which are regularly arranged in a plurality of arrays on the substrate, and in each of which information is magnetically recorded, and
the low magnetic section is a between-dot separator provided between the magnetic dots and obstructing mutual magnetic coupling of the magnetic dots.
